(19) United States
(12) Patent Application Publication
(10) Pub. No.: US 2023/0299771 A1
(43) Pub. Date: Sep. 21, 2023

(54) VOLTAGE LEVEL SHIFTING AND CONNECTIONS WITH TOUCH ELECTRODES INCLUDING THE SAME

(71) Applicant: Microchip Technology Incorporated, Chandler, AZ (US)

(72) Inventors: Viktor Aase, Ranheim (NO); Lei Zou, Olso (NO)

(21) Appl. No.: 18/180,692

(22) Filed: Mar. 8, 2023

Related U.S. Application Data
(60) Provisional application No. 63/269,408, filed on Mar. 16, 2022.

(51) Int. Cl. H03K 19/0185; H03K 17/96; G06F 3/041

(52) U.S. Cl. CPC H03K 19/018521; H03K 17/96; G06F 3/04164; G06F 3/0446

(57) ABSTRACT

One or more examples relate to voltage level shifting. An example apparatus may include first and second inputs, an output, and a circuit. The first and second inputs may receive compliments of a signal represented by first voltage levels. The output may provide the signal represented by second voltage levels. The circuit may change voltage levels utilized to represent the signal from first voltage levels to second voltage levels. The circuit may include cross-coupled first high voltage switches, a pair of series coupled switches, and a pair of voltage clamping switches. The cross-coupled first high voltage switches may selectively couple the output to a high voltage node responsive to a high voltage level of the signal. The pair of series coupled switches may comprising respective second high voltage switches, and the pair of series coupled switches may selectively couple the output to a first voltage supply. The pair of voltage clamping switches may increase OFF-resistance of the respective second high voltage switches of the pair of series coupled switches responsive to a low voltage level at the respective input.

### CROSS-REFERENCE TO RELATED APPLICATION

This application claims the benefit under 35 U.S.C. § 119(e) of the priority date of U.S. Provisional Patent Application Ser. No. 63/269,408, filed Mar. 16, 2022, for HIGH VOLTAGE LEVEL SHIFTER AND CONNECTIONS WITH TOUCH ELECTRODES INCLUDING THE SAME, the contents and disclosure of which is incorporated herein in its entirety by this reference.

### FIELD

One or more examples relate, generally, to voltage level shifting, and more specifically, to voltage level shifting circuits with increased immunity to leakage current.

### BACKGROUND

In various electronic devices, integrated circuits (IC) that operate at supply voltages interface with electronic devices, electric circuits, and integrated circuits that operate at higher supply voltages.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 is a circuit diagram of a voltage level shifter to voltage level shift voltages utilized to represent a signal from first voltage levels to second voltage levels that are higher than the first voltage levels, in accordance with one or more examples.

FIG. 2 a timing diagram depicting voltage signals for a contemplated operation of voltage level shifter of FIG. 1, in accordance with one or more examples.

FIG. 3 is a simplified block diagram depicting an apparatus for connecting a touch electrode to receiver or driver circuitry of a mutual sensing system, in accordance with one or more examples.

FIG. 4 is a flow diagram depicting a process for changing voltage levels utilized to represent a signal from first voltage levels to second voltage levels that are higher than the first voltage levels, in accordance with one or more examples.

FIG. 5 is a block diagram of circuitry that, in some examples, may be used to implement various functions, operations, acts, processes, or processes disclosed herein.

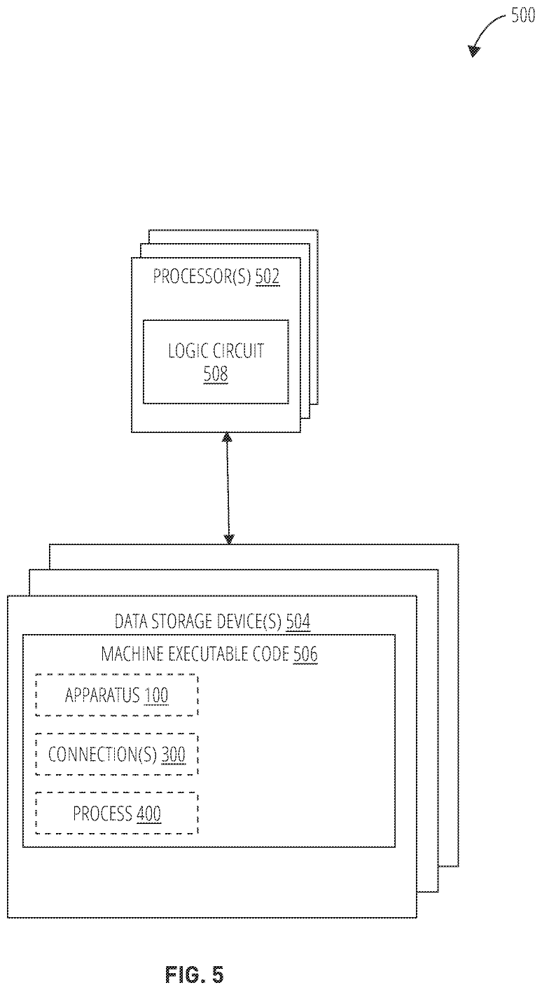

### DETAILED DESCRIPTION

In the following detailed description, reference is made to the accompanying drawings, which form a part hereof, and in which are shown, by way of illustration, specific examples of examples in which the present disclosure may be practiced. These examples are described in sufficient detail to enable a person of ordinary skill in the art to practice the present disclosure. However, other examples enabled herein may be utilized, and structural, material, and process changes may be made without departing from the scope of the disclosure.

The illustrations presented herein are not meant to be actual views of any particular method, system, device, or structure, but are merely idealized representations that are employed to describe the examples of the present disclosure. In some instances, similar structures or components in the various drawings may retain the same or similar numbering for the convenience of the reader; however, the similarity in numbering does not necessarily mean that the structures or components are identical in size, composition, configuration, or any other property.

The following description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example or this disclosure to the specified components, steps, features, functions, or the like.

It will be readily understood that the components of the examples as generally described herein and illustrated in the drawings could be arranged and designed in a wide variety of different configurations. Thus, the following description of various examples is not intended to limit the scope of the present disclosure, but is merely representative of various examples. While the various aspects of the examples may be presented in the drawings, the drawings are not necessarily drawn to scale unless specifically indicated.

Furthermore, specific implementations shown and described are only examples and should not be construed as the only way to implement the present disclosure unless specified otherwise herein. Elements, circuits, and functions may be shown in block diagram form in order not to obscure the present disclosure in unnecessary detail. Conversely, specific implementations shown and described are exemplary only and should not be construed as the only way to implement the present disclosure unless specified otherwise herein. Additionally, block definitions and partitioning of logic between various blocks is exemplary of a specific implementation. It will be readily apparent to one of ordinary skill in the art that the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

Those of ordinary skill in the art would understand that information and signals may be represented using any of a variety of different technologies and techniques. Some drawings may illustrate signals as a single signal for clarity of presentation and description. It will be understood by a person of ordinary skill in the art that the signal may represent a bus of signals, wherein the bus may have a variety of bit widths and the present disclosure may be implemented on any number of data signals including a single data signal.

The various illustrative logical blocks, modules, and circuits described in connection with the examples disclosed herein may be implemented or performed with a general purpose processor, a special purpose processor, a digital signal processor (DSP), an integrated circuit (IC), an Application Specific integrated circuit (ASIC), a Field Programmable Gate Array (FPGA) or other programmable logic device, discrete gate or transistor logic, discrete hardware components, or any combination thereof designed to perform the functions described herein. A general-purpose processor (may also be referred to herein as a host processor or simply a host) may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors in conjunction with a DSP core, or any other such configuration. A general-purpose computer including a processor is considered a special-purpose computer while the general-purpose computer is configured to execute computing instructions (e.g., software code) related to examples of the present disclosure.

The examples may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged. A process may correspond to a method, a thread, a function, a procedure, a subroutine, a subprogram, other structure, or combinations thereof. Furthermore, the methods disclosed herein may be implemented in hardware, software, or both. If implemented in software, the functions may be stored or transmitted as one or more instructions or code on computer-readable media. Computer-readable media includes both computer storage media and communication media including any medium that facilitates transfer of a computer program from one place to another.

Any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. In addition, unless stated otherwise, a set of elements may comprise one or more elements.

As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

In this description, the term “coupled” and derivatives thereof may be used to indicate that two elements co-operate or interact with each other. When an element is described as being “coupled” to another element, then the elements may be in direct physical or electrical contact or there may be intervening elements or layers present. In contrast, when an element is described as being “directly coupled” to another element, then there are no intervening elements or layers present. The terms “on” and “connected” may be used in this description interchangeably with the term “coupled,” and have the same meaning unless expressly indicated otherwise or the context would indicate otherwise to a person having ordinary skill in the art.

Mutual capacitance is the capacitive coupling between objects, and in the case of touch sensors, the capacitive coupling between intersections of electrodes serving as transmitters (transmitter electrodes) and electrodes serving as receivers (receiver electrodes), also sometimes referred to as “X electrodes” and “Y electrodes,” respectively. In a typical arrangement for mutual capacitance sensing, transmitter electrodes and receiver electrodes are respectively arranged in a grid of rows and columns. A respective one of the intersections of the transmitter and receiver electrodes each referred to herein as a “sensor node.” The transmitter electrodes are driven with voltage pulses that inject current into the receiver electrode's capacitance via mutual capacitance (CM) coupling between the transmitter and receiver electrodes. A grounded object in suitable proximity to a sensor node shunts away some of the charge via a capacitively coupled ground path, and so appears to an observer (i.e., a measurement circuit) to change (e.g., decrease) the mutual capacitance between the transmitter and receiver electrodes intersecting at that sensor node. Mutual capacitance sensing involves detecting such changes in mutual capacitance.

A controller integrated circuit (IC) referred to herein as a “touch IC” is coupled to respective X and Y electrodes via respective sensing pads and controls the mutual sensing process via a suitable mutual sensing technique. Various techniques and circuits implementing the same may be utilized to generate a voltage signal indicative of an associated mutual capacitance CM. A non-limiting example of a suitable technique is utilization of a relaxation oscillator that oscillates with a frequency indicative of an associated mutual capacitance. Another non-limiting example of a suitable technique is utilization of a circuit that tracks a time-to-charge a capacitance of a sensor node to a predetermined voltage or that tracks an amount a sensor node is charged over a predetermined period of time—time to charge or amount charged being indicative of mutual capacitance. Another non-limiting example of a suitable technique is utilization of a capacitive voltage divider circuit, where, if the sensor node and connector are respectively charged to predetermined voltages and then share charge there between, a resultant voltage at an associated capacitor is indicative of a change in capacitance at the sensor node. Another non-limiting example of a suitable technique is utilization of a charge transfer circuit that accumulates charge onto an integrating capacitor and the voltage across the integrating capacitor, which is indicative of mutual capacitance, is compared to a reference voltage or read by an analog-to-digital converter for comparison to a threshold value. Another non-limiting example of a suitable technique is utilization of sigma-delta modulation where a voltage across an external capacitor is modulated about a reference voltage in charge-up and charge-down operations and the time duration of these operations is indicative of mutual capacitance.

Whether X electrodes (rows) or Y electrodes (columns) are assigned as transmitter electrodes or receiver electrodes in a given mutual capacitance sensing system (“mutual sensing system”) is a matter of design choice, and may be hardwired (immutable) or configurable to varying degrees. In a mutual sensing system where the operational state of an electrode is configurable as a receiver or transmitter, a connection between a sensing pad and logic of a touch IC may include transistor switches (“switches”) to couple an associated electrode (i.e., an electrode coupled to the sensing pad) to one of receiver circuitry or driver circuitry of the touch IC and thereby configure an operational state of the electrode as a receiver or a transmitter.

In the case of connections that include complementary metal-oxide-semiconductor (CMOS) switches, to reliably turn a switch ON or OFF, the voltage signals that control the switches (“control signals”) utilize voltage levels at the periphery of the range of the voltage levels utilized by the voltage signals of the receiver and transmitter circuitry of the touch IC (“sensing signals”). Sometimes the switch control logic (e.g., implemented by a processing core, without limitation) of a touch IC may generate the control signals for the switches, however, the voltage levels utilized by switch control logic to generate the voltage signals are lower than the voltage levels that will turn ON or OFF such a switch.

To address the difference in voltage levels, a voltage level shifter may be utilized at a control terminal of a switch (e.g., a gate terminal, without limitation) to receive the control signals generated by switch control logic, and change the voltage levels utilized to represent the control signals from first voltage levels to second, higher, voltage levels. The control signals utilizing the second, higher, voltage levels are provided to the control terminal of the switch.

In a typical voltage level shifter known to inventors of this disclosure, a supply voltage at the second voltage levels provides the reference voltage utilized to convert the voltage levels utilized to represent input signal, e.g., the control signals generated by switch control logic, from the first voltage levels to the second voltage levels.

The inventors of this disclosure appreciate that it would be desirable (in touch sensing applications, but also other applications) to generate a reference voltage for a voltage level shifter at a predetermined voltage level, on-chip, and optionally, responsive to a preset value that represents a desired voltage level for the reference voltage. Circuits for generating a voltage on-chip (referred to herein as an “on-chip voltage source”) typically have weaker current-driving capability than a chip's voltage supply, and so are prone to weakening.

As a non-limiting example, an on-chip charge pump has a weaker current driving capability than a voltage supply due at least in part to limited fly capacitor values implemented on-chip. Load current may affect (e.g., reduce, without limitation) the voltage level of the reference voltage. Generally, the less load current the more constant the voltage level generated by an on-chip voltage source. Direct current (DC) type leakage current exhibited by a voltage level shifter draws on the current driven by the on-chip voltage source, which can pull-down the voltage level of an output voltage. In a case, like the one described above, where a voltage level shifter changes the voltage levels utilized to represent control signals for a switch, if the second voltage levels are unintentionally lower due to load current, the control signals may not be reliable, as a non-limiting example, reliable to control switches or other devices that require a control signals at higher voltage levels.

Leakage current includes, but is not limited to, unwanted current draw due to temperatures above threshold for switches, sub-threshold leakage current due to insufficient gate driving voltages to fully turn OFF a switch, and parasitic leakage current due to parasitic devices that form in the CMOS structure of a switch such as PN junctions, without limitation. Using a PMOS transistor as an example, a PMOS transistor exhibits only tiny leakage current up to 125 degrees Celsius (with negligible effect on a reference voltage generated by an on-chip voltage source discussed above), but an NMOS transistor exhibits high leakage current at high temperature(>80 degrees Celsius), which leakage current increases sharply thereafter with increasing temperature, and so the leakage current at >80 degrees Celsius is not negligible, and can negatively affect reference voltage generated by an on-chip voltage source, and switch control, as discussed above.

Accordingly, the inventors of this disclosure appreciate a need for a voltage level shifter that reduces leakage current and, accordingly, load current that might otherwise pull-down voltages levels at the output of the voltage level shifter.

One or more examples relate, generally, to increasing the OFF resistance of one or more switches (e.g., NMOS switches, without limitation) while voltage level shifting, which may reduce leakage current at such NMOS switches, as a non-limiting example, due to temperature or drain-source voltages across the switch.

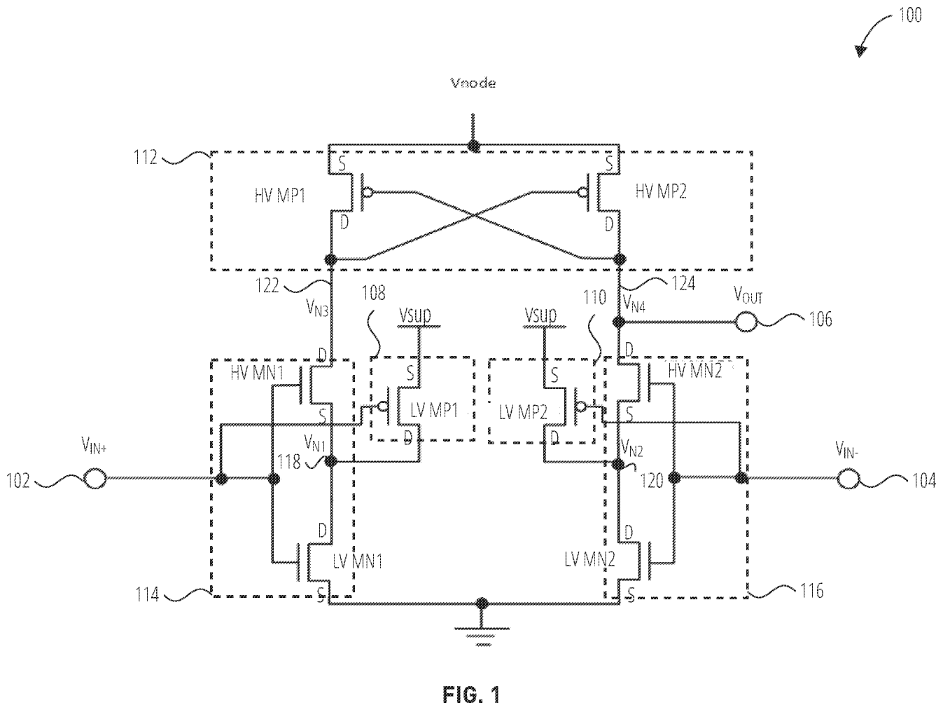

FIG. 1 is a circuit diagram of an apparatus 100 to voltage level shift voltages utilized to represent a signal, in accordance with one or more examples. Apparatus 100 may also be referred to herein as a “voltage level shifter 100.”

Voltage level shifter 100 includes complimentary inputs: first input 102 and second input 104; output 106; cross-coupled switches 112 coupled to output 106; first series coupled switches 114 between first input 102 and output 106; second series coupled switches 116 between second input 104 and output 106; a pair of voltage clamping switches: first voltage clamping switch 108 between a voltage supply and node 118 (node 118 being between first series coupled switches 114), and second voltage clamping switch 110 coupled between the voltage supply and node 120 (node 120 being between second series coupled switches 116).

Complimentary inputs, first input 102 and second input 104, are connectors (e.g., terminals, without limitation) to receive compliments of a signal represented by first voltage levels. Output 106 is a connector (e.g., a terminal, without limitation) to provide the signal represented by second voltage levels. The first voltage levels utilized to represent the signal and the second voltage levels utilized to represent the signal are different. In one or more examples, the first voltage levels and the second voltage levels may be logic voltage levels. In one or more examples, a logic high level (i.e., a voltage level utilized to represent a logic high) of the first voltage levels is less than a logic high level (i.e., a voltage level utilized to represent a logic high) of the second voltage levels. In one or more examples, the first voltage levels are CMOS logic levels, and the second voltage levels are TTL logic levels. It is known that some CMOS logic levels are lower than TTL logic levels. As a non-limiting example, CMOS logic levels may be 0V for low level to 3.3V for high level or 0V for low level to 1.2V for high level, and TTL logic levels may be 0V for low level to 5V for high levels. Use of other logic level conventions than CMOS or TTL does not exceed the scope of this disclosure. In one or more examples, the first voltage levels may be CMOS or TTL logic levels, and the second voltage levels are logic levels suitable to control a HV switch, logic levels at the periphery of the range of the voltage levels of voltage signals utilized by the receiver and transmitter circuitry of the touch IC, or both (if they are the same).

First voltage clamping switch 108 clamps a voltage level at node 118 located between first series coupled switches 114 responsive to a low level (0 volts or ground) at first input 102. Second voltage clamping switch 110 clamps a voltage level at node 120 located between second series coupled switches 116 responsive to low level (0 volts or ground) at second input 104.

First voltage clamping switch 108 and second voltage clamping switch 110 are operable to boost (increase) OFF-resistances of first series coupled switches 114 and second series coupled switches 116, respectively, and the boosted OFF resistance reduces leakage current exhibited at first series coupled switches 114 and second series coupled switches 116.

Cross-coupled switches 112 include HV PMOS switches HV MP1 and HV MP2 with their respective sources coupled to a high source voltage, Vnode. Voltage Vnode is a reference voltage for representing a high level according to the second voltage levels for representing a signal.

A LV switch is a switch capable of supporting gate voltages and drain-source voltages typically associated with logic level ranges utilized in ICs, e.g., CMOS logic levels (e.g., about 0V to about 3.3V) or TTL logic levels (e.g., about 0V to about 5V). A HV switch is a switch capable of supporting higher gate voltages and drain-source voltages (e.g., a high level in the range of about 10V to about 20V, without limitation), e.g., higher than a LV switch, without limitation. As a non-limiting example, LV or HV characteristics may be due to the selected process option to manufacture the switch. As a non-limiting example, a HV NMOS switch may have a deep well at drain or source and a thicker gate oxide than a LV NMOS switch (accordingly, a LV NMOS switch may have no deep well at drain or source and a thinner gate oxide than a HV NMOS switch), which can sustain higher electric fields without causing breakdown. As a non-limiting example, a HV PMOS switch may have a deep well at drain or source and a thicker gate oxide (accordingly, a LV PMOS switch may have no deep well at drain or source and a thinner gate oxide), which can sustain higher electric fields without causing breakdown.

First series coupled switches 114 and second series coupled switches 116 respectively include low voltage (LV) NMOS switches LV MN1, LV MN2 with their respective sources coupled with ground voltage (or to a first voltage supply to provide a ground voltage), and high voltage (HV) NMOS switches HV MN1, HV MN2 with their respective sources coupled with the respective drains of LV NMOS switches LV MN1, LV MN2. Respective drains of HV NMOS switches HV MN1 and HV MN2 are coupled with respective drains of HV PMOS switches HV MP1 and HV MP2 at nodes 122 and 124. Respective gates of HV PMOS switches HV MP1 and HV MP2 are coupled to nodes 124 and 122, respectively, and thus coupled with respective drains of HV NMOS switches HV MN2 and HV MN1.

First voltage clamping switch 108 and second voltage clamping switch 110 are respectively LV PMOS switches LV MP1 and LV MP with their respective sources coupled to a supply voltage Vsup (or to a second voltage supply or Vsup supply) and respective drains coupled to nodes 118, 120. Respective gates of HV NMOS switch HV MN1, LV NMOS switch LVMN1, and LV PMOS switch LV PM1 are coupled to first input 102. Respective gates of HV NMOS switch HV MN2, LV NMOS switch LVMN2, and LV PMOS switch LV PM2 are coupled second input 104.

In a contemplated operation, discussed below, the voltage Vsup is for representing a high level for the first voltage levels utilized to represent a signal, voltage Vnode is for representing a high level for a the second voltage levels utilized to represent a signal, and ground voltage is for representing low level for both the first voltage levels and the second voltage levels. The voltage level of high source voltage Vnode is greater than the voltage level of low supply voltage Vsup. As noted, these could be different types of logic levels. Alternatively, the second voltage levels could be much higher, for example, voltage levels utilized to drive touch measurements in touch screens, as discussed, below. The voltages Vnode, ground, and Vsup may be considered reference voltages, e.g., Vnode is a first reference voltage, ground a second reference voltage, and Vsup a third reference voltage.

### Example #1: V_{IN+} is Low Level (Ground), V_{IN-} is High Level (Vsup)

When the voltage V_{IN+} at first input 102 is a low level (e.g., 0V), the gate voltage Vg for switch LV MP1 is low level and switch LV MP1 is ON. The voltage level of voltage V_{N1} at node 118 is set to the level of supply voltage V_{SUP} because when switch LV MP1 is ON it electrically couples node 118 with supply voltage V_{SUP}. The gate voltage Vg for switch LV MN1 is low level and switch LV MN1 is OFF. The gate voltage Vg for switch HV MN1 is low level and switch HV MN1 is OFF. Assuming supply voltage V_{SUP} is 3.3V, the gate-source voltage of Vgs for switch HV MN1 is Vg−Vs=0−3.3V=−3.3V, which boosts the OFF resistance of switch HV MN1. A negative gate-source voltage Vgs at switch HV MN1 induces a reverse-bias condition between the gate and source regions of switch HV MN1, which reduces the number of free carriers in the channel and increases the channel resistance, which decreases leakage current.

When the voltage V_{IN+} at first input 102 is a low level (e.g., 0 V) the voltage V_{IN-} at second input 104 is a high level-the compliment of a low level-so the gate voltage Vg for switch LV MP2 is high level and switch LV MP2 is OFF. The gate voltage Vg for switch LV MN2 is high level and switch LV MN2 is ON. The voltage VN2 at node 120 is set to ground because when switch LV MN2 is ON it electrically couples node 120 with the ground voltage. The gate voltage Vgs for switch HV MN2 is high level and so switch HV MN2 is ON. The voltage VN4 at node 124 is set to ground voltage because switch HV MN2 and switch LV MN2 are both ON and electrically couple node 124 to the ground voltage.

When voltages V_{IN+} and V_{IN-} are low level and high level, respectively, the voltage VN4 at node 124 is ground voltage. The gate voltage at switch HV MP1 is 0V, so switch HV MP1 is ON. The voltage VN3 at node 122 is set to Vnode because when switch HV MP1 is ON it electrically couples node 122 with voltage Vnode. The gate voltage at switch HV MP2 is set to voltage Vnode and switch HV MP2 is OFF. The voltage Vout at output 106 is set to ground voltage by the series coupling of node 124 to ground by second series coupled switches 116.

Notably, the drain-source voltage Vds of switch HV MN1 is Vds=Vnode−Vsup. Vnode is a high value (e.g., 2× or more than Vsup, without limitation), the drain-source voltage Vds on switch HV MN1 could create free carriers in the channel between the drain and source of switch HV MN1, which induces leakage current. Free carriers and leakage current could be generated or further exacerbated by high temperatures, as discussed above. The reverse-bias condition between the gate and source regions of switch HV MN1 reduces the number of free carriers in the channel, and thus, reduces the effects of the high drain-source voltage Vds, effects of high temperature, or effects of both, on switch HV MN1.

### Example #2: V_{IN+} is High Level (Vsup), V_{IN-} is Low Level (Ground)

When the voltage V_{IN+} at first input 102 is a high level (Vsup), the gate voltage Vg for switch LV MP1 is high level and so switch LV MP1 is OFF. The gate voltage Vg for switch LV MN1 is high level and so switch LV MN1 is ON. The voltage V_{N1} at node 118 is set to low level because when switch LV MN1 is ON it electrically couples node 118 with the ground voltage. The gate voltage Vg for switch HV MN1 is high level and so switch HV MN2 is ON.

When the voltage V_{IN+} at first input 102 is a high level the voltage V_{IN-} at second input 104 is at a low level-the compliment of a high level-so the gate voltage Vgs for switch LV MP2 is low level and switch LV MP2 is ON. The voltage level of voltage V_{N1} at node 120 is set to the level of supply voltage V_{SUP} because when switch LV MP2 is ON it electrically couples node 120 with the voltage supply for V_{SUP}. The gate voltage Vg for switch LV MN2 is 0V and so switch LV MN2 is OFF. The gate voltage Vg for switch HV MN2 is low level and switch HV MN2 is OFF. Assuming supply voltage Vsup is 3.3V, then the gate-source voltage of Vgs for switch HV MN2 is Vg−Vs=0−3.3V=−3.3V, which boosts the OFF resistance of switch HV MN2. A negative gate-source voltage Vgs at switch HV MN2 induces a reverse-bias condition between the gate and source regions of switch HV MN2, which reduces the number of free carriers in the channel and increases the channel resistance, which decreases leakage current.

When voltages V_{IN+} and V_{IN-} are high and low, respectively, the voltage VN3 at node 122 is set to ground voltage by the electrical coupling of node 122 with ground supply by first series coupled switches 114. The gate-source voltage Vgs of switch HV MP2 is Vnode, so switch HV MP2 is ON. The voltage VN4 at node 124 is set to Vnode because when switch HV MP2 is ON it electrically couples the voltage source for voltage Vnode with node 124. The gate-source voltage at switch HV MP1 is 0V so HV MP1 is OFF. The voltage Vout at output 106 is set to voltage Vnode by the electrical coupling of node 124 with voltage supply for voltage Vnode by switch HV MP2.

Notably, the drain-source voltage Vds of switch HV MN2 is Vds=Vnode−Vsup. Vnode is a high voltage node (e.g., 2× or more than Vsup), the drain-source voltage Vds on switch HV MN2 could create free carriers in the channel between the drain and source of switch HV MN2, which induces leakage current. Free carriers and leakage current could be generated or further exacerbated by high temperatures, as discussed above. The reverse-bias condition between the gate and source regions of switch HV MN1 reduces the number of free carriers in the channel, and thus, reduces the effects of the high drain-source voltage Vds, effects of high temperature, or effects of both on switch HV MN2.

While HV PMOS switches typically exhibit better leakage current immunity than HV NMOS switches, clamping circuits may be included with the HV PMOS switches HV MP1 and HVMP2 without exceeding the scope of this disclosure.

In one or more examples, voltage level shifter 100 may be utilized with a range of voltage levels for voltage Vnode and voltage Vsup, and wide temperature ranges. The circuit topology depicted by FIG. 1 which includes LV NMOS switches LV MN1 and LV MN2 switchably coupling ground with node 118 and node 120, respectively, is particularly efficient when Vsup=3.3V. In one or more examples, HV NMOS switches may be utilized instead of LV NMOS switches LV MN1 and LV MN2 when Vsup=3.3V, and optionally, HV PMOS switches may be utilized instead of LV PMOS switches LV MP1 and LV MP2-though such a circuit topology may exhibit less power efficiency than the circuit topology depicted by FIG. 1. In one or more examples, HV NMOS switches may be utilized instead of LV NMOS switches LV MN1 and LV MN2 when Vsup=1.2V, and optionally, HV PMOS switches may be utilized instead of LV PMOS switches LV MP1 and LV MP2. In cases where Vsup=1.2V— and reduce leakage current from voltage Vnode.

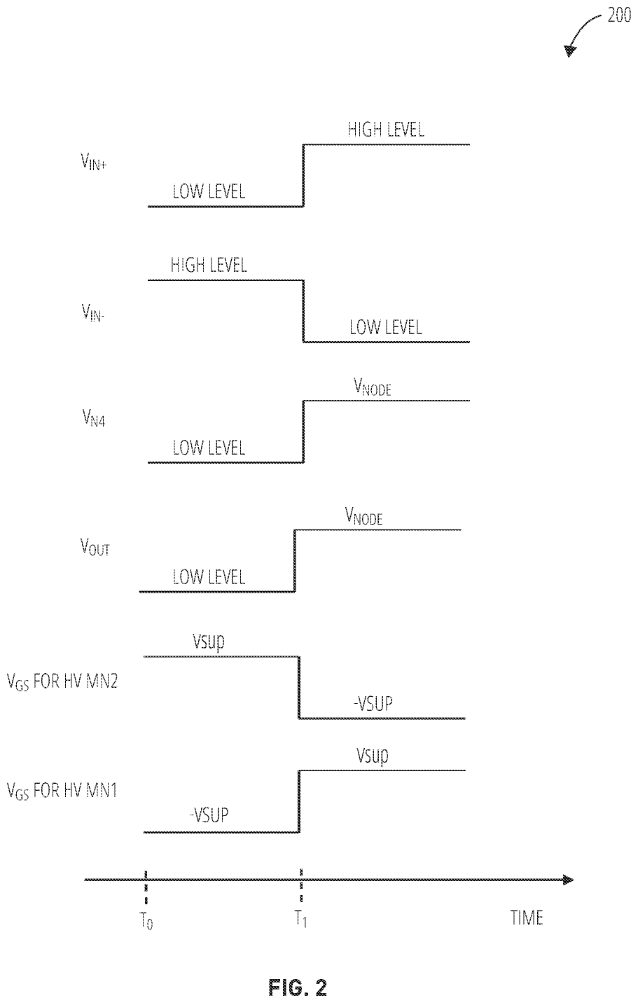

FIG. 2 is a timing diagram depicting voltage signals 200 for a contemplated operation of voltage level shifter 100, in accordance with one or more examples. Depicted are voltage levels for V_{N+}, V_{IN-}, V_{N1}, V_{N2}, and V_{OUT} when an input signal is received by voltage level shifter 100 depicted by FIG. 1. Signal delay due, as a non-limiting example, to time for switches to turn ON or OFF, is omitted from FIG. 2 to avoid unnecessarily obscuring the depiction and discussion.

As depicted, when V_{IN+} is low level V_{IN-} is high level, voltage VN3 is low level and voltage Vout is low level. The gate-source voltage Vgs for switch HV MN1 is −V_{SUP}, and gate-source voltage Vgs for switch HV MN2 is V_{SUP}.

When V_{IN+} is high level, V_{IN-} is low level, voltage VN3 is level-shifted high (Vnode) and voltage Vout is level-shifted high (Vnode). The gate-source voltage Vgs for switch HV MN1 is V_{SUP}, and gate-source voltage Vgs for switch HV MN2 is −V_{SUP}.

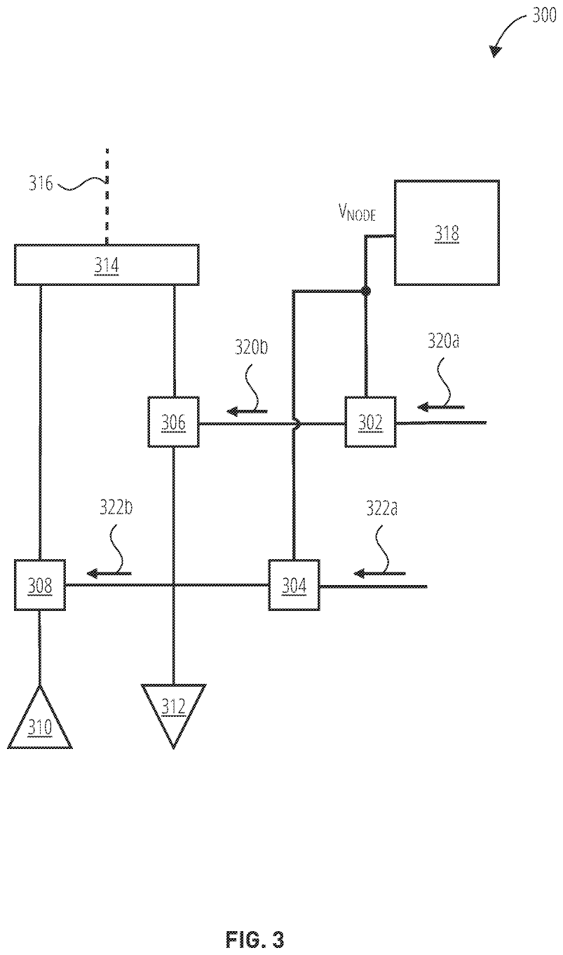

FIG. 3 is a simplified block diagram depicting an apparatus 300 for connecting a touch electrode to receiver or driver circuitry of a mutual sensing system, in accordance with one or more examples. Apparatus 300 may also be referred to herein as a “connection 300.”

Connection 300 includes HV switch 306 to couple pad 314 with receiver circuitry 312 of the mutual sensing system, and HV switch 308 to couple pad 314 with driver circuitry 310 of the mutual sensing system. An optional on-chip voltage source 318 provides a reference voltage Vnode to HV level shifter 302 and HV level shifter 304 to utilize for the second voltage levels. In one or more examples, HV level shifter 302 and HV level shifter 304 are voltage level shifters 100 of FIG. 2.

Connection 300 optionally includes electrode 316 that may selectively exhibit multiple states, including a receiver electrode responsive to control signals 320a/320b for turning ON HV switch 306 (for switchably coupling electrode 316 with receiver circuitry 312 via pad 314 and HV switch 306), and control signals 322a/322b for turning OFF HV switch 308 (for switchably de-coupling electrode 316 with driver circuitry 310 via pad 314 and HV switch 306); and a transmitter electrode responsive to control signals 320a/320b for turning ON HV switch 308 (for switchably coupling electrode 316 with driver circuitry 310 via pad 314 and HV switch 308), and control signals 322a/322b for turning OFF HV switch 306 (for switchably de-coupling electrode 316 with receiver circuitry 312 via pad 314 and HV switch 306).

As a non-limiting example, on-chip voltage source 318 may be an on-chip charge pump capable of generating, as a non-limiting example, 10V. Connections between HV level shifter 302 and HV level shifter 304 to ground supply voltage are present by not depicted.

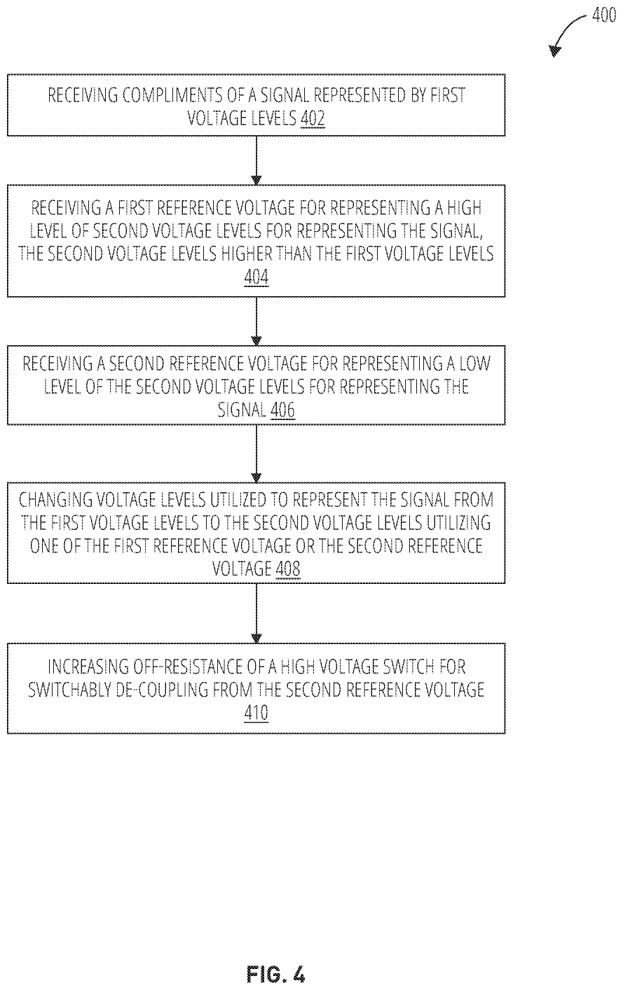

FIG. 4 is a flow diagram depicting a process 400 for changing voltage levels utilized to represent a signal from first voltage levels to second voltage levels, in accordance with one or more examples.

Although the example process 400 depicts a particular sequence of operations, the sequence may be altered without departing from the scope of the present disclosure. For example, some of the operations depicted may be performed in parallel or in a different sequence that does not materially affect the function of the process 400. In other examples, different components of an example device or system that implements the process 400 may perform functions at substantially the same time or in a specific sequence.

According to some examples, process 400 includes receiving compliments of a signal represented by first voltage levels at operation 402.

According to some examples, process 400 includes receiving a first reference voltage for representing a high level of second voltage levels for representing the signal, the second voltage levels higher than the first voltage levels at operation 404. The first reference voltage may be Vnode of FIG. 1, a voltage generated by an on-chip voltage source 318 of FIG. 3, or a voltage generated by an on-chip charge pump.

According to some examples, process 400 includes receiving a second reference voltage for representing a low level of the second voltage levels for representing the signal at operation 406. The second reference voltage may be ground or 0V, such as a ground voltage depicted in FIG. 1.

According to some examples, process 400 includes changing voltage levels utilized to represent the signal from the first voltage levels to the second voltage levels utilizing one of the first reference voltage or the second reference voltage at operation 408.

According to some examples, process 400 includes increasing OFF-resistance of a high voltage switch for switchably de-coupling from the second reference voltage at operation 410. In various instances, the high voltage switch may be switch HV MN1 when switchably de-coupling node 122 from ground supply (i.e., the source of the second reference voltage) or switch HV MN2 when switchably de-coupling node 124 from ground supply (i.e., the source of the second reference voltage).

It will be appreciated by those of ordinary skill in the art that functional elements of examples disclosed herein (e.g., functions, operations, acts, processes, or methods) may be implemented in any suitable hardware, software, firmware, or combinations thereof. FIG. 1 illustrates non-limiting examples of implementations of functional elements disclosed herein. In some examples, some or all portions of the functional elements disclosed herein may be performed by hardware capable of carrying out the functional elements.

FIG. 1 is a block diagram of a circuitry 500 that, in some examples, may be used to implement various functions, operations, acts, processes, or methods disclosed herein. The circuitry 500 includes one or more processors 502 (sometimes referred to herein as “processors 502”) operably coupled to one or more data storage devices 504 (sometimes referred to herein as “storage 504”). The storage 504 includes machine executable code 506 stored thereon and the processors 502 include logic circuit 508. The machine executable code 506 information describing functional elements that may be implemented by (e.g., performed by) the logic circuit 508. The logic circuit 508 is adapted to implement (e.g., perform) the functional elements described by the machine executable code 506. The circuitry 500, when executing the functional elements described by the machine executable code 506, should be considered as special purpose hardware for carrying out functional elements disclosed herein. In some examples the processors 502 may perform the functional elements described by the machine executable code 506 sequentially, concurrently (e.g., on one or more different hardware platforms), or in one or more parallel process streams.

When implemented by logic circuit 508 of the processors 502, the machine executable code 506 adapts the processors 502 to perform operations of examples disclosed herein. By way of non-limiting example, the machine executable code 506 may adapt the processors 502 to perform some or a totality of operations of one or more of process 400.

Also by way of non-limiting example, the machine executable code 506 may adapt the processors 502 to perform some or a totality of features, functions, or operations disclosed herein for one or more of: voltage level shifter 100 or a connection 300. More specifically, features, functions, or operations disclosed herein for one or more of: voltage level shifter 100, including one or more of: cross-coupled switches 112, first series coupled switches 114, first voltage clamping switch 108, second voltage clamping switch 110, or second series coupled switches 116; or connection 300, including one or more of: HV level shifter 302, HV level shifter 304, HV switch 306, HV switch 308, driver circuitry 310, receiver circuitry 312, pad 314, electrode 316, or on-chip voltage source 318.

The processors 502 may include a general purpose processor, a special purpose processor, a central processing unit (CPU), a microcontroller, a programmable logic controller (PLC), a digital signal processor (DSP), an application specific integrated circuit (ASIC), a field-programmable gate array (FPGA) or other programmable logic device, discrete gate or transistor logic, discrete hardware components, other programmable device, or any combination thereof designed to perform the functions disclosed herein. A general-purpose computer including a processor is considered a special-purpose computer while the general-purpose computer executes functional elements corresponding to the machine executable code 506 (e.g., software code, firmware code, hardware descriptions) related to examples of the present disclosure. It is noted that a general-purpose processor (may also be referred to herein as a host processor or simply a host) may be a microprocessor, but in the alternative, the processors 502 may include any conventional processor, controller, microcontroller, or state machine. The processors 502 may also be implemented as a combination of computing devices, such as a combination of a DSP and a microprocessor, a plurality of microprocessors, one or more microprocessors in conjunction with a DSP core, or any other such configuration.

In some examples the storage 504 includes volatile data storage (e.g., random-access memory (RAM)), non-volatile data storage (e.g., Flash memory, a hard disc drive, a solid state drive, erasable programmable read-only memory (EPROM), without limitation). In some examples the processors 502 and the storage 504 may be implemented into a single device (e.g., a semiconductor device product, a system on chip (SOC), without limitation). In some examples the processors 502 and the storage 504 may be implemented into separate devices.

In some examples the machine executable code 506 may include computer-readable instructions (e.g., software code, firmware code). By way of non-limiting example, the computer-readable instructions may be stored by the storage 504, accessed directly by the processors 502, and executed by the processors 502 using at least the logic circuit 508. Also by way of non-limiting example, the computer-readable instructions may be stored on the storage 504, transferred to a memory device (not shown) for execution, and executed by the processors 502 using at least the logic circuit 508. Accordingly, in some examples the logic circuit 508 includes electrically configurable logic circuit 508.

In some examples the machine executable code 506 may describe hardware (e.g., circuitry) to be implemented in the logic circuit 508 to perform the functional elements. This hardware may be described at any of a variety of levels of abstraction, from low-level transistor layouts to high-level description languages. At a high-level of abstraction, a hardware description language (HDL) such as an IEEE Standard hardware description language (HDL) may be used. By way of non-limiting examples, Verilog, SystemVerilog or very large scale integration (VLSI) hardware description language (VHDL) may be used.

HDL descriptions may be converted into descriptions at any of numerous other levels of abstraction as desired. As a non-limiting example, a high-level description can be converted to a logic-level description such as a register-transfer language (RTL), a gate-level (GL) description, a layout-level description, or a mask-level description. As a non-limiting example, micro-operations to be performed by hardware logic circuits (e.g., gates, flip-flops, registers, without limitation) of the logic circuit 508 may be described in a RTL and then converted by a synthesis tool into a GL description, and the GL description may be converted by a placement and routing tool into a layout-level description that corresponds to a physical layout of an integrated circuit of a programmable logic device, discrete gate or transistor logic, discrete hardware components, or combinations/subcombinations thereof. Accordingly, in some examples the machine executable code 506 may include an HDL, an RTL, a GL description, a mask level description, other hardware description, or any combination thereof.

In examples where the machine executable code 506 includes a hardware description (at any level of abstraction), a system (not shown, but including the storage 504) implements the hardware description described by the machine executable code 506. By way of non-limiting example, the processors 502 may include a programmable logic device (e.g., an FPGA or a PLC) and the logic circuit 508 may be electrically controlled to implement circuitry corresponding to the hardware description into the logic circuit 508. Also by way of non-limiting example, the logic circuit 508 may include hard-wired logic manufactured by a manufacturing system (not shown, but including the storage 504) according to the hardware description of the machine executable code 506. By way of non-limiting examples, when features, functions, or implemented by hard-wired logic, logic circuit 508 may be understood to be permanently configured to perform some or a totality of features, functions, or operations of examples described above.

Regardless of whether the machine executable code 506 includes computer-readable instructions or a hardware description, the logic circuit 508 is adapted to perform the functional elements described by the machine executable code 506 when implementing the functional elements of the machine executable code 506. It is noted that although a hardware description may not directly describe functional elements, a hardware description indirectly describes functional elements that the hardware elements described by the hardware description are capable of performing.

As used in the present disclosure, the term “combination” with reference to a plurality of elements may include a combination of all the elements or any of various different subcombinations of some of the elements. For example, the phrase “A, B, C, D, or combinations thereof” may refer to any one of A, B, C, or D; the combination of each of A, B, C, and D; and any subcombination of A, B, C, or D such as A, B, and C; A, B, and D; A, C, and D; B, C, and D; A and B; A and C; A and D; B and C; B and D; or C and D.

Terms used in the present disclosure and especially in the appended claims (e.g., bodies of the appended claims, without limitation) are generally intended as “open” terms (e.g., the term “including” should be interpreted as “including, but not limited to,” the term “having” should be interpreted as “having at least,” the term “includes” should be interpreted as “includes, but is not limited to,” without limitation). As used herein, the term “each” means some or a totality. As used herein, the term “each and every” means a totality.

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more,” without limitation); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations, without limitation). Furthermore, in those instances where a convention analogous to “at least one of A, B, and C, etc.,” or “one or more of A, B, and C, etc.,” is used, in general such a construction is intended to include A alone, B alone, C alone, A and B together, A and C together, B and C together, or A, B, and C together, etc.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additional non-limiting examples of the disclosure include:

Example 1: An apparatus, comprising: first and second inputs to receive compliments of a signal represented by first voltage levels; an output to provide the signal represented by second voltage levels; and a circuit to change voltage levels utilized to represent the signal from first voltage levels to second voltage levels, the circuit comprising: cross-coupled first high voltage switches to selectively couple the output to a high voltage node responsive to a high voltage level of the signal; a pair of series coupled switches comprising respective second high voltage switches, the pair of series coupled switches to selectively couple the output to a first voltage supply; and a pair of voltage clamping switches to increase OFF-resistance of the respective second high voltage switches of the pair of series coupled switches responsive to a low voltage level at the respective input.

Example 2: The apparatus according to Example 1, wherein the pair of series coupled switches comprises respective first low voltage switches series coupled with the respective second high voltage switches.

Example 3: The apparatus according to any of Examples 1 and 2, wherein the second high voltage switches comprise respective high voltage NMOS switches, and the first low voltage switches comprises respective low voltage NMOS switches.

Example 4: The apparatus according to any of Examples 1 through 3, wherein a source of the first low voltage NMOS switches is coupled with the first voltage supply.

Example 5: The apparatus according to any of Examples 1 through 4, wherein a source of the high voltage NMOS switches is coupled with a drain of the low voltage NMOS switch.

Example 6: The apparatus according to any of Examples 1 through 5, wherein the pair of series coupled switches comprises respective further high voltage switches series coupled with the respective second high voltage switches.

Example 7: The apparatus according to any of Examples 1 through 6, wherein the second high voltage switches comprise respective high voltage NMOS switches, and the further high voltage switches comprises respective high voltage NMOS switches.

Example 8: The apparatus according to any of Examples 1 through 7, wherein a source of the further high voltage NMOS switches is coupled with the first voltage supply.

Example 9: The apparatus according to any of Examples 1 through 8, wherein the pair of voltage clamping switches comprises respective second low voltage switches.

Example 10: The apparatus according to any of Examples 1 through 9, wherein the second low voltage switches comprise respective low voltage PMOS switches.

Example 11: The apparatus according to any of Examples 1 through 10, wherein a source of the low voltage PMOS switches is coupled to a second voltage supply, a gate of the respective low voltage PMOS switches is coupled to a respective one of the inputs, and a drain of the low voltage PMOS switch is coupled to an internal node of a respective one of the pair of series coupled switches.

Example 12: The apparatus according to any of Examples 1 through 11, the pair of voltage clamping switches comprises respective second high voltage switches.

Example 13: The apparatus according to any of Examples 1 through 12, wherein the cross-coupled first high voltage switches comprise respective high voltage PMOS switches.

Example 14: The apparatus according to any of Examples 1 through 13, wherein a source of the first high voltage PMOS switches is coupled with a voltage node for operative coupling to an on-chip voltage source comprising a charge pump to provide the high voltage.

Example 15: An apparatus, comprising: a touch receiver circuitry; a touch driver circuitry; an on-chip pad to operable couple with an electrode of a touch sensor; high voltage switches for alternately coupling, responsive to control signals, the on-chip pad with the touch driver circuitry or the touch receiver circuitry; level shifters for changing voltage levels utilized to represent control signals from first voltage levels to second voltage levels, wherein the second voltage levels are different than the first voltage levels; and an on-chip voltage source to provide a reference voltage for the second voltage levels.

Example 16: The apparatus according to Example 15, wherein the on-chip voltage source comprising a charge pump.

Example 17: The apparatus according to any of Examples 15 and 16, wherein the level shifters respectively comprise: inputs to receive compliments of a signal represented by first voltage levels; an output to provide the signal represented by second voltage levels; an integrated circuit, comprising: a circuit to change voltage levels utilized to represent the signal from the first voltage levels to the second voltage levels; and a voltage source to provide a high voltage utilized by the circuit to change voltage levels from first voltage levels to second voltage levels.

Example 18: The apparatus according to any of Examples 15 through 17, wherein a voltage level of the high voltage is greater than the first voltage levels.

Example 19: A method, comprising: receiving compliments of a signal represented by first voltage levels; receiving a first reference voltage for representing a high level of second voltage levels for representing the signal, the second voltage levels higher than the first voltage levels; receiving a second reference voltage for representing a low level of the second voltage levels for representing the signal; changing voltage levels utilized to represent the signal from the first voltage levels to the second voltage levels utilizing one of the first reference voltage or the second reference voltage; and increasing OFF-resistance of a high voltage switch for switchably de-coupling from the second reference voltage.

While the present disclosure has been described herein with respect to certain illustrated embodiments, those of ordinary skill in the art will recognize and appreciate that the present invention is not so limited. Rather, many additions, deletions, and modifications to the illustrated and described embodiments may be made without departing from the scope of the invention as hereinafter claimed along with their legal equivalents. In addition, features from one embodiment may be combined with features of another embodiment while still being encompassed within the scope of the invention as contemplated by the inventors.

What is claimed is:

1. An apparatus, comprising:
first and second inputs to receive compliments of a signal represented by first voltage levels;
an output to provide the signal represented by second voltage levels; and
a circuit to change voltage levels utilized to represent the signal from first voltage levels to second voltage levels, the circuit comprising:
cross-coupled first high voltage switches to selectively couple the output to a high voltage node responsive to a high voltage level of the signal;
a pair of series coupled switches comprising respective second high voltage switches, the pair of series coupled switches to selectively couple the output to a first voltage supply; and
a pair of voltage clamping switches to increase OFF-resistance of the respective second high voltage switches of the pair of series coupled switches responsive to a low voltage level at the respective input.

2. The apparatus of claim 1, wherein the pair of series coupled switches comprises respective first low voltage switches series coupled with the respective second high voltage switches.

3. The apparatus of claim 2, wherein the second high voltage switches comprise respective high voltage NMOS switches, and the first low voltage switches comprises respective low voltage NMOS switches.

4. The apparatus of claim 3, wherein a source of the first low voltage NMOS switches is coupled with the first voltage supply.

5. The apparatus of claim 3, wherein a source of the high voltage NMOS switches is coupled with a drain of the low voltage NMOS switch.

6. The apparatus of claim 1, wherein the pair of series coupled switches comprises respective further high voltage switches series coupled with the respective second high voltage switches.

7. The apparatus of claim 6, wherein the second high voltage switches comprise respective high voltage NMOS switches, and the further high voltage switches comprises respective high voltage NMOS switches.

8. The apparatus of claim 6, wherein a source of the further high voltage NMOS switches is coupled with the first voltage supply.

9. The apparatus of claim 1, wherein the pair of voltage clamping switches comprises respective second low voltage switches.

10. The apparatus of claim 9, wherein the second low voltage switches comprise respective low voltage PMOS switches.

11. The apparatus of claim 10, wherein a source of the low voltage PMOS switches is coupled to a second voltage supply, a gate of the respective low voltage PMOS switches is coupled to a respective one of the inputs, and a drain of the low voltage PMOS switch is coupled to an internal node of a respective one of the pair of series coupled switches.

12. The apparatus of claim 1, the pair of voltage clamping switches comprises respective second high voltage switches.

13. The apparatus of claim 1, wherein the cross-coupled first high voltage switches comprise respective high voltage PMOS switches.

14. The apparatus of claim 13, wherein a source of the first high voltage PMOS switches is coupled with a voltage node for operative coupling to an on-chip voltage source comprising a charge pump to provide the high voltage.

15. An apparatus, comprising:
a touch receiver circuitry;
a touch driver circuitry;
an on-chip pad to operable couple with an electrode of a touch sensor;
high voltage switches for alternately coupling, responsive to control signals, the on-chip pad with the touch driver circuitry or the touch receiver circuitry;
level shifters for changing voltage levels utilized to represent control signals from first voltage levels to second voltage levels, wherein the second voltage levels are different than the first voltage levels; and
an on-chip voltage source to provide a reference voltage for the second voltage levels.

16. The apparatus of claim 15, wherein the on-chip voltage source comprising a charge pump.

17. The apparatus of claim 15, wherein the level shifters respectively comprise:
inputs to receive compliments of a signal represented by first voltage levels;
an output to provide the signal represented by second voltage levels;
an integrated circuit, comprising:
a circuit to change voltage levels utilized to represent the signal from the first voltage levels to the second voltage levels; and
a voltage source to provide a high voltage utilized by the circuit to change voltage levels from first voltage levels to second voltage levels.

18. The apparatus of claim 15, wherein a voltage level of the high voltage is greater than the first voltage levels.

19. A method, comprising:
receiving compliments of a signal represented by first voltage levels;
receiving a first reference voltage for representing a high level of second voltage levels for representing the signal, the second voltage levels higher than the first voltage levels;
receiving a second reference voltage for representing a low level of the second voltage levels for representing the signal;
changing voltage levels utilized to represent the signal from the first voltage levels to the second voltage levels utilizing one of the first reference voltage or the second reference voltage; and
increasing OFF-resistance of a high voltage switch for switchably de-coupling from the second reference voltage.
